(19) United States
(12) Patent Application Publication
(10) Pub. No.: US 2022/0367467 A1
(43) Pub. Date: Nov. 17, 2022

(54) MEMORY DEVICE USING PILLAR-SHAPED SEMICONDUCTOR ELEMENT

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 17/739,762

(22) Filed: May 9, 2022

(30) Foreign Application Priority Data
May 11, 2021 (JP) PCT/JP2021/017840

(51) Int. Cl. H01L 27/108

(52) U.S. Cl. CPC H01L 27/10802

(57) ABSTRACT

An N⁺ layer 21 connected to a source line SL on a substrate 20 has thereon first Si pillars 22aa to 22da. The Si pillars 22aa to 22da are surrounded, and Lg1 between opposing intersections among intersections between a line X-X′ and outer peripheral edges of HfO₂ layers 24a serving as gate insulating layers surrounding the Si pillars 22aa and 22ba is larger than a thickness Lg2 of the HfO₂ layers 24a crossing a line Y-Y′ and is smaller than twice the thickness Lg2. Further, TiN layers 25aa and 25ba are connected to plate lines PL1a and PL1br, and TiN layers 25ab and 25bb are connected to plate lines PL2a and PL2b, the TiN layers 25aa and 25ba and the TiN layers 25ab and 25bb surrounding the HfO₂ layers 24a, extending in the line X-X′ direction, and being separated from each other. Further, TiN layers 27a and 27b surround Si pillars 22ab to 22db respectively positioned on the Si pillars 22aa to 22da and are connected to word lines WL1 and WL2, and metal wiring layers 32a and 32b are connected to N⁺ layers 28a to 28d positioned on the Si pillars 22ab to 22db and are connected to bit lines BL1 and BL2. As a result, a dynamic flash memory cell is formed.

### CROSS-REFERENCE TO RELATED APPLICATIONS

This application claims priority to PCT/JP2021/017840 filed May 11, 2021, the enter content of which is incorporated herein by reference.

### TECHNICAL FIELD

The present invention relates to a memory device using a pillar-shaped semiconductor element.

### BACKGROUND ART

Recent development of LSI (Large Scale Integration) technology requires high integration and high performance of semiconductor devices including memory elements.

In typical planar MOS transistors, a channel extends in a horizontal direction along an upper surface of a semiconductor substrate. In contrast, a channel of SGTs extends in a direction vertical to the upper surface of the semiconductor substrate (see, for example, PTL 1 and NPL 1). This enables the SGTs to achieve a high-density semiconductor device compared with the planar MOS transistors. Such SGTs can be used as selection transistors to implement high-integration memories such as a DRAM (Dynamic Random Access Memory, see, for example, NPL 2) to which a capacitor is connected, a PCM (Phase Change Memory, see, for example, NPL 3) to which a resistance change element is connected, an RRAM (Resistive Random Access Memory, see, for example, NPL 4), and an MRAM (Magneto-resistive Random Access Memory, see, for example, NPL 5) in which a change in magnetic spin orientation is induced by current to change resistance. Further, a capacitorless DRAM memory cell (see NPL 6) constituted by a single MOS transistor, and the like are available. The present application relates to a semiconductor device including a dynamic flash memory that does not include a resistance change element or a capacitor and that can be constituted only by MOS transistors.

FIGS. 8A to 8D illustrate a write operation of the capacitorless DRAM memory cell described above, which is constituted by a single MOS transistor, FIGS. 9A and 9B illustrate a problem in operation, and FIGS. 10A to 10C illustrate a read operation (see NPLs 6 to 10).

FIGS. 8A to 8D illustrate the write operation of the DRAM memory cell. FIG. 8A illustrates a “1” write state.

Here, the memory cell is formed on an SOI substrate 100 and is constituted by a source N⁺ layer 103 (semiconductor regions containing donor impurities at high concentrations are hereinafter referred to as “N⁺ layers”) to which a source line SL is connected, a drain N⁺ layer 104 to which a bit line BL is connected, a gate conductive layer 105 to which a word line WL is connected, and a floating body 102 of a MOS transistor 110a; the capacitorless DRAM memory cell is constituted by the single MOS transistor 110a. A SiO₂ layer 101 of the SOI substrate 100 is immediately below and in contact with the floating body 102. To write “1” to the memory cell constituted by the single MOS transistor 110a, the MOS transistor 110a is operated in a saturation region. That is, an electron channel 107 extending from the source N⁺ layer 103 has a pinch-off point 108 and does not reach the drain N⁺ layer 104 to which the bit line BL is connected. When the MOS transistor 110a is operated such that the bit line BL connected to the drain N⁺ layer 104 and the word line WL connected to the gate conductive layer 105 are both set to be at a high voltage and the gate voltage is set to about ½ of the drain voltage, the electric field strength is maximized at the pinch-off point 108 near the drain N⁺ layer 104. As a result, accelerated electrons flowing from the source N⁺ layer 103 toward the drain N⁺ layer 104 collide with a Si lattice, and the kinetic energy lost at this time causes generation of electron-hole pairs (impact ionization phenomenon). Most of the generated electrons (not illustrated) reach the drain N⁺ layer 104. A very small number of electrons, which are very hot, jump over a gate oxide film 109 and reach the gate conductive layer 105. Holes 106, which are generated at the same time, charge the floating body 102. In this case, the generated holes 106 contribute as an increment of the majority carriers because the floating body 102 is made of P-type Si. When the floating body 102 is filled with the generated holes 106 and the voltage of the floating body 102 becomes higher than that of the source N⁺ layer 103 by Vb or more, the generated holes 106 are further discharged to the source N⁺ layer 103. Here, Vb is the built-in voltage across a PN junction between the source N⁺ layer 103 and the P-layer floating body 102 and is about 0.7 V. FIG. 8B illustrates a state in which the floating body 102 is charged to saturation with the generated holes 106.

Next, a “0” write operation of a memory cell 110 will be described with reference to FIG. 8C. A selected word line WL is common to the memory cell 110a for writing “1” and a memory cell 110b for writing “0”, which are present randomly. FIG. 8C illustrates a state of rewriting from the “1” write state to a “0” write state. To write “0”, the voltage of the bit line BL is set to a negative bias, and the PN junction between the drain N⁺ layer 104 and the P-layer floating body 102 is forward biased. As a result, the holes 106 in the floating body 102, which are generated in advance in the previous cycle, flow into the drain N⁺ layer 104 connected to the bit line BL. At the completion of the write operation, the following two memory cell states are obtained: the memory cell 110a filled with the generated holes 106 (FIG. 8B) and the memory cell 110b from which the generated holes 106 are injected (FIG. 8C). The floating body 102 of the memory cell 110a filled with the holes 106 has a higher potential than the floating body 102 having no generated holes. Thus, a threshold voltage of the memory cell 110a is lower than a threshold voltage of the memory cell 110b. This state is illustrated in FIG. 8D.

Next, a problem in the operation of the memory cell constituted by the single MOS transistor will be described with reference to FIGS. 9A and 9B. As illustrated in FIG. 9A, the floating body 102 has a capacitance C_{FB}, which is the sum of a capacitance C_{WL} between the gate to which the word line WL is connected and the floating body 102, a junction capacitance C_{SL} of the PN junction between the source N⁺ layer 103 to which the source line SL is connected and the floating body 102, and a junction capacitance C_{BL} of the PN junction between the drain N⁺ layer 104 to which the bit line BL is connected and the floating body 102. The capacitance C_{FB} is expressed by the following equation.

C_{FB}=C_{WL}+C_{BL}+C_{SL} (1)

Accordingly, an oscillation of a word line voltage V_{WL} at the time of writing affects the voltage of the floating body 102 serving as a storage node (junction) of the memory cell. This state is illustrated in FIG. 9B. In response to an increase in the word line voltage V_{WL} from 0 V to V_{ProgWL} at the time of writing, a voltage V_{FB} of the floating body 102 increases from a voltage V_{FB1} in the initial state before the change in the word line voltage V_{WL} to V_{FB2} due to capacitive coupling with the word line WL. The amount of voltage change ΔV_{FB} is expressed by the following equation.

ΔV_{FB}=V_{FB2}−V_{FB1}=C_{WL}/(C_{WL}+C_{BL}+C_{SL}×V_{ProgWL} (2)

Here,

β=C_{WL}/(C_{WL}+C_{BL}+C_{SL}) (3)

β represents a coupling ratio. In such a memory cell, the contribution ratio of C_{WL} is high, and, for example, C_{WL}:C_{BL}:C_{SL}:C_{SL}=8:1:1. In this case, β is equal to 0.8. For example, when the word line WL changes from 5 V at the time of writing to 0 V after the completion of writing, the floating body 102 is subjected to an amplitude noise of 5V×β=4 V due to the capacitive coupling between the word line WL and the floating body 102. This causes a problem that a sufficient potential difference margin is not provided between the “1” potential and the “0” potential of the floating body at the time of writing.

FIGS. 10A to 10C illustrate the read operation. FIG. 10A illustrates a “1” write state, and FIG. 10B illustrates a “0” write state. Actually, however, even if Vb is written in the floating body 102 by “1” writing, the floating body 102 is lowered to a negative bias when the word line WL returns to 0 V in response to the completion of writing. When “0” is written, the floating body 102 is lowered to a further negative bias, which makes it difficult to provide a sufficiently large potential difference margin between “1” and “0” at the time of writing. The small operation margin is a major problem of the DRAM memory cell. An issue is how the DRAM memory cell and a peripheral circuit for driving the DRAM memory cell are to be formed on the same substrate.

### CITATION LIST

### Patent Literature

[PTL 1] Japanese Unexamined Patent Application Publication No. 2-188966

### Non Patent Literature

[NPL 1] Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)
[NPL 2] H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)
[NPL 3] H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp. 2201-2227 (2010)
[NPL 4] T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)
[NPL 5] W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)
[NPL 6] M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)
[NPL 7] J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012)
[NPL 8] T. Ohsawa, K. Fujita, T. Higashi, Y. Iwata, T. Kajiyama, Y. Asao, and K. Sunouchi: “Memory design using a one-transistor gain cell on SOI,” IEEE JSSC, vol. 37, No. 11, pp 1510-1522 (2002).
[NPL 9] T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond,” IEEE IEDM (2006).
[NPL 10] E. Yoshida, T. Tanaka: “A Design of a Capacitorless 1T-DRAM Cell Using Gate-induced Drain Leakage (GIDL) Current for Low-power and High-speed Embedded Memory,” IEEE IEDM (2003).
[NPL 11] E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-697, April 2006.

### SUMMARY OF INVENTION

### Technical Problem

A capacitorless single-transistor DRAM (gain cell) in a memory device using an SGT has a problem that oscillation of the potential of the word line at the time of reading or writing data is directly transmitted as noise to a SGT body in a floating state because the capacitive coupling between the word line and the SGT body is large. This causes a problem of erroneous reading or erroneous rewriting of stored data, and makes it difficult to put a capacitorless single-transistor DRAM (gain cell) into practical use. In addition to overcoming the problem described above, it is necessary to form a memory cell and a peripheral circuit for driving the memory cell on the same substrate at high density and low cost.

### Solution to Problem

To overcome the problem described above, a memory device according to the present invention includes:

a first semiconductor pillar, a second semiconductor pillar, a third semiconductor pillar, and a fourth semiconductor pillar standing on a substrate in a vertical direction to the substrate, the first semiconductor pillar and the second semiconductor pillar having center points on a first straight line in plan view and being arranged adjacent to each other, the third semiconductor pillar and the fourth semiconductor pillar having center points on a second straight line parallel to the first line in plan view and being arranged adjacent to each other;

a first impurity region connected to bottom portions of the first to fourth semiconductor pillars;

first gate insulating layers positioned above the first impurity region in the vertical direction and each surrounding a side surface of a corresponding one of the first to fourth semiconductor pillars;

a first gate conductor layer and a second gate conductor layer surrounding the respective first gate insulating layers of the first semiconductor pillar and the second semiconductor pillar in plan view and each extending to be continuous along the first straight line, the first gate conductor layer and the second gate conductor layer being separated from each other in plan view;

a third gate conductor layer and a fourth gate conductor layer surrounding the respective first gate insulating layers of the third semiconductor pillar and the fourth semiconductor pillar in plan view and each extending to be continuous along the second straight line, the third gate conductor layer and the fourth gate conductor layer being separated from each other in plan view;

fifth to eighth semiconductor pillars positioned on top of the first to fourth semiconductor pillars, respectively;

second gate insulating layers positioned above the first gate insulating layers in the vertical direction and each surrounding a side surface of a corresponding one of the fifth to eighth semiconductor pillars;

a fifth gate conductor layer and a sixth gate conductor layer surrounding the second gate insulating layers and having upper surfaces positioned below top portions of the fifth to eighth semiconductor pillars, the fifth gate conductor layer and the sixth gate conductor layer being separated from the first to fourth gate conductor layers in the vertical direction, the fifth gate conductor layer surrounding the fifth semiconductor pillar and the sixth semiconductor pillar and extending to be continuous along the first straight line, the sixth gate conductor layer surrounding the seventh semiconductor pillar and the eighth semiconductor pillar and extending to be continuous along the second straight line;

second impurity regions each positioned at the top portion of a corresponding one of the fifth to eighth semiconductor pillars;

a first wiring conductor layer connected to the second impurity region at the top portion of the fifth semiconductor pillar and the second impurity region at the top portion of the seventh semiconductor pillar; and

a second wiring conductor layer connected to the second impurity region at the top portion of the sixth semiconductor pillar and the second impurity region at the top portion of the eighth semiconductor pillar,

in plan view, the first gate insulating layers lie between two opposing intersections among intersections between the first straight line and two outer peripheral edges of the first semiconductor pillar and the second semiconductor pillar, and the first gate insulating layers lie between two opposing intersections among intersections between the second straight line and two outer peripheral edges of the third semiconductor pillar and the fourth semiconductor pillar, and

the memory device is configured to control a voltage to be applied to the first to sixth gate conductor layers, a voltage to be applied to the first impurity region, and a voltage to be applied to the second impurity regions to perform a data write operation, a data read operation, and a data erase operation (first aspect of the invention).

In the first aspect of the invention described above, in plan view, a first length between the two opposing intersections among the intersections between the first straight line and the two outer peripheral edges of the first semiconductor pillar and the second semiconductor pillar is smaller than twice a second length and is greater than or equal to the second length, the second length being a thickness of a portion of each of the first gate insulating layers that is not shared with another of the first gate insulating layers (second aspect of the invention).

In the second aspect of the invention described above, in plan view, an outer peripheral edge of the respective first gate insulating layers surrounding the first semiconductor pillar and the second semiconductor pillar and an outer peripheral edge of the respective first gate insulating layers surrounding the third semiconductor pillar and the fourth semiconductor pillar are spaced apart from each other in a direction perpendicular to the first straight line (third aspect of the invention).

In the first aspect of the invention described above, the second gate conductor layer and the third gate conductor layer are connected to each other in plan view (fourth aspect of the invention).

In the third aspect of the invention described above, in plan view, the first gate conductor layer and the fourth gate conductor layer are connected to gate conductor layers lying at outer peripheral portions of pluralities of semiconductor pillars outwardly adjacent to the first to fourth semiconductor pillars and lying in the same layer as the first gate conductor layer and the fourth gate conductor layer (fifth aspect of the invention).

In the first aspect of the invention described above, in plan view, respective first outer peripheral edges of the fifth to eighth semiconductor pillars surrounded by the second gate insulating layers are positioned inside respective second outer peripheral edges of the first to fourth semiconductor pillars surrounded by the first gate insulating layers (sixth aspect of the invention).

In the first aspect of the invention described above, the memory device is configured to perform the data write operation for holding a hole group or an electron group serving as majority carriers generated by an impact ionization phenomenon or a gate induced drain leakage current in any or all of the first to eighth semiconductor pillars, and the data erase operation for controlling the voltage to be applied to the first to sixth gate conductor layers, the voltage to be applied to the first impurity region, and the voltage to be applied to the second impurity regions to remove the hole group or the electron group serving as the majority carriers from within any or all of the first to eighth semiconductor pillars (seventh aspect of the invention).

In the first aspect of the invention described above, a first gate capacitance between the first to fourth gate conductor layers and the first to fourth semiconductor pillars is larger than a second gate capacitance between the fifth to sixth gate conductor layers and the fifth to eighth semiconductor pillars (eighth aspect of the invention).

### BRIEF DESCRIPTION OF DRAWINGS

FIGS. 1A and 1B are diagrams illustrating a structure of a dynamic flash memory cell according to a first embodiment.

FIGS. 2A, 2B, and 2C are diagrams for describing an erase operation mechanism of the dynamic flash memory cell according to the first embodiment.

FIGS. 3A, 3B, and 3C are diagrams for describing a write operation mechanism of the dynamic flash memory cell according to the first embodiment.

FIGS. 4AA, 4AB, and 4AC are diagrams for describing a read operation mechanism of the dynamic flash memory cell according to the first embodiment.

FIGS. 4BA, 4BB, 4BC, and 4BD are diagrams for describing a read operation mechanism of the dynamic flash memory cell according to the first embodiment.

FIGS. 5A, 5B, 5C, and 5D are diagrams for describing a structure of a dynamic flash memory device according to the first embodiment.

FIGS. 6A, 6B, 6C, and 6D are diagrams for describing a structure of a dynamic flash memory device according to a second embodiment.

FIGS. 7A, 7B, 7C, and 7D are diagrams for describing a structure of a dynamic flash memory device according to a third embodiment.

FIGS. 8A, 8B, 8C, and 8D are diagrams illustrating a write operation of a capacitorless DRAM memory cell of the related art.

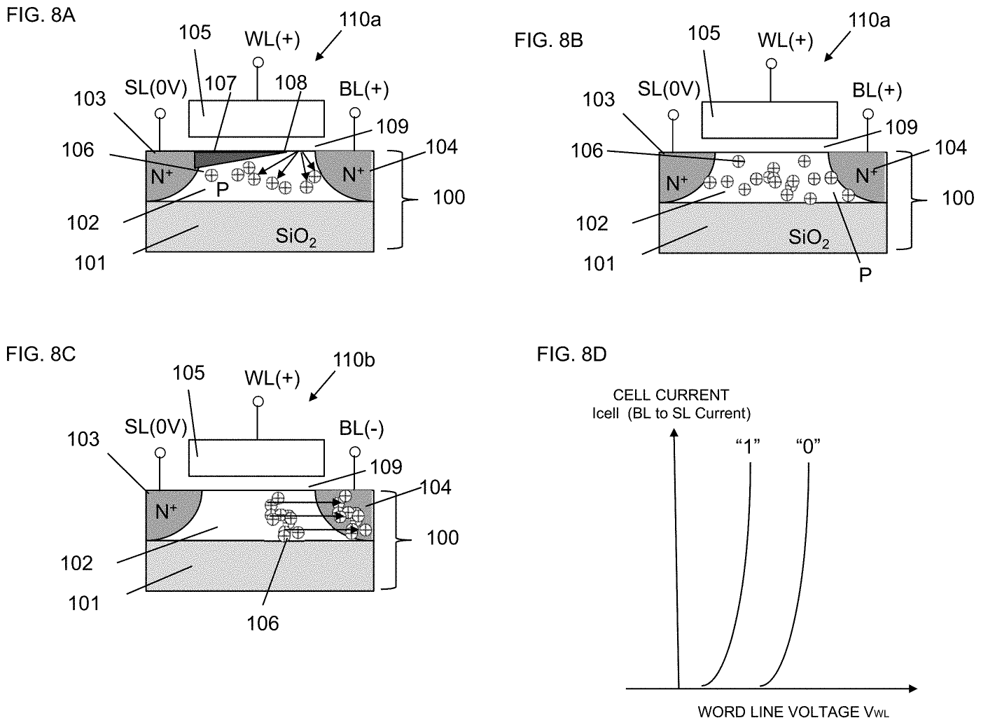

FIGS. 9A and 9B are diagrams for describing a problem in the operation of the capacitorless DRAM memory cell of the related art.

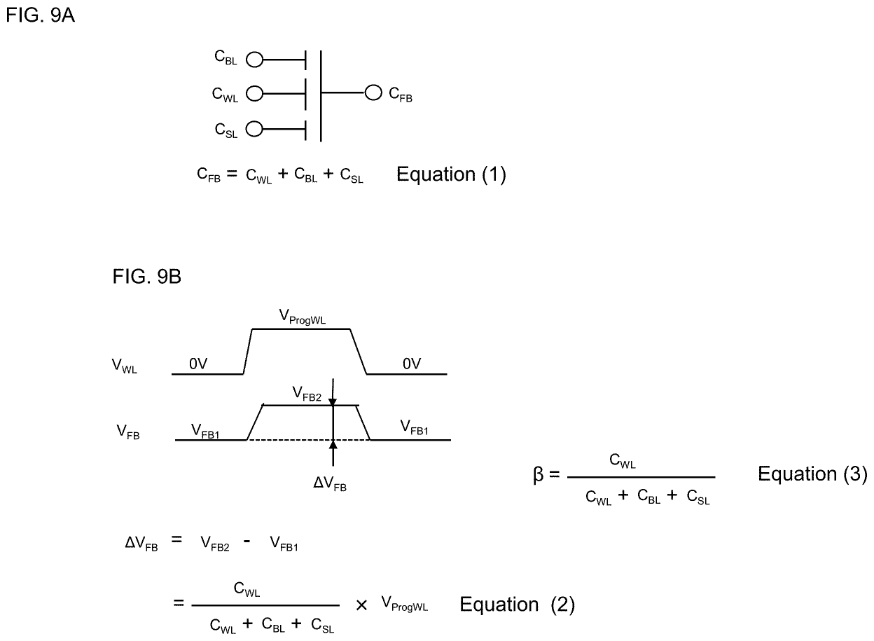

FIGS. 10A, 10B, and 10C are diagrams illustrating a read operation of the capacitorless DRAM memory cell of the related art.

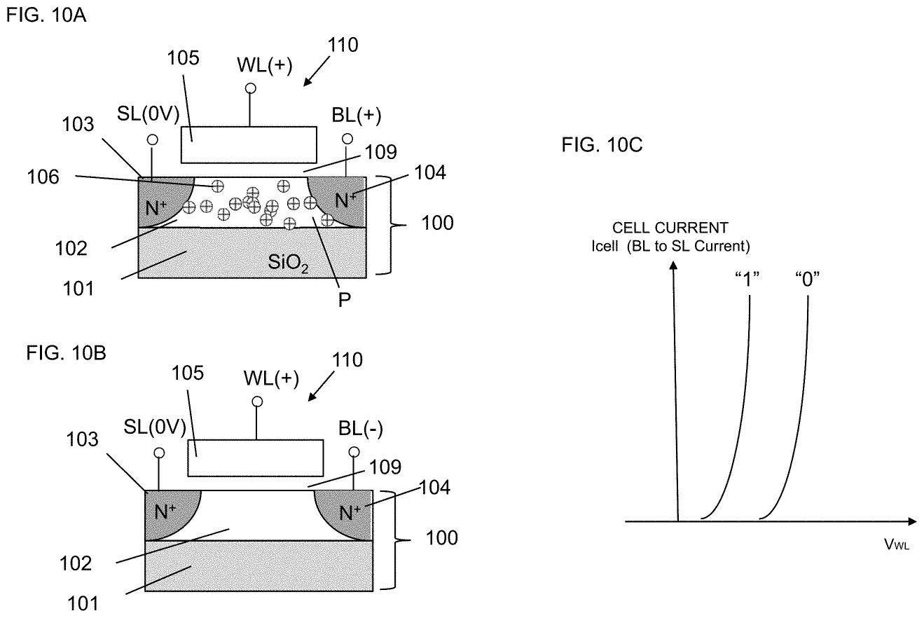

### DESCRIPTION OF EMBODIMENTS

Hereinafter, the structure and operation of embodiments of a memory device using a semiconductor element (hereinafter referred to as a dynamic flash memory device) according to the present invention will be described with reference to the drawings.

### First Embodiment

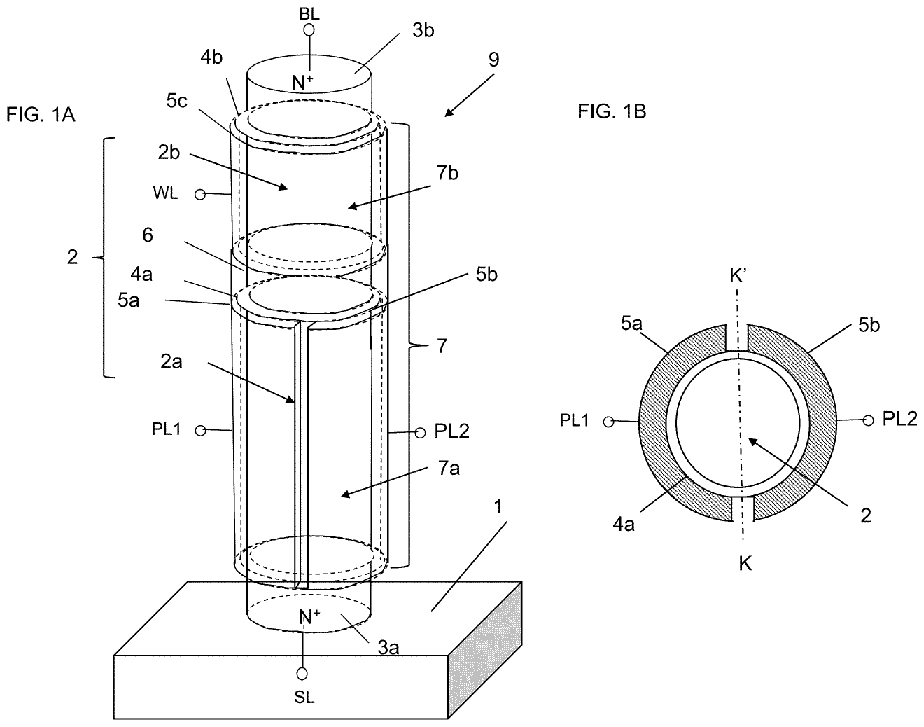

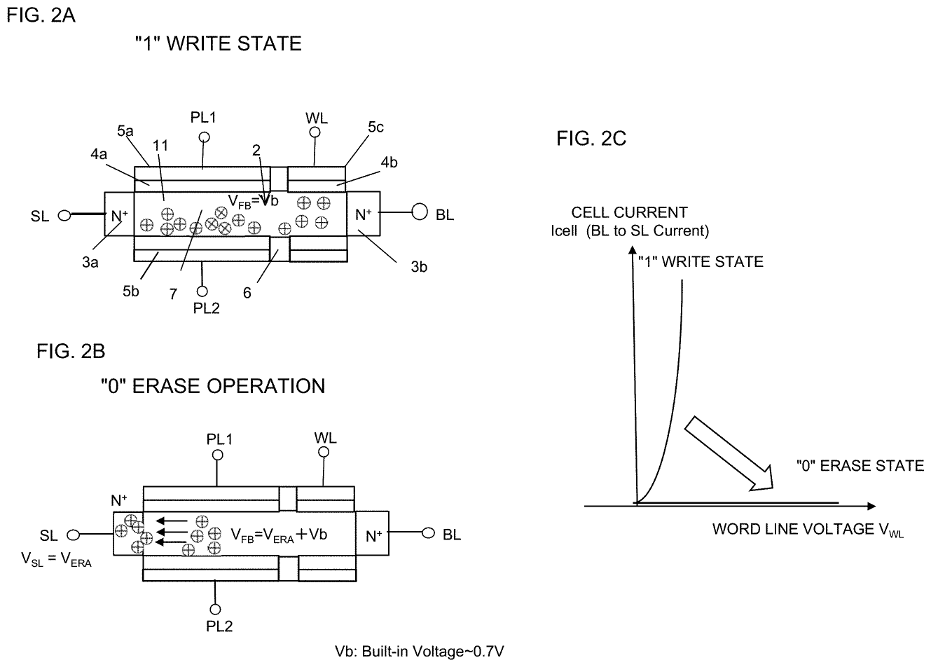

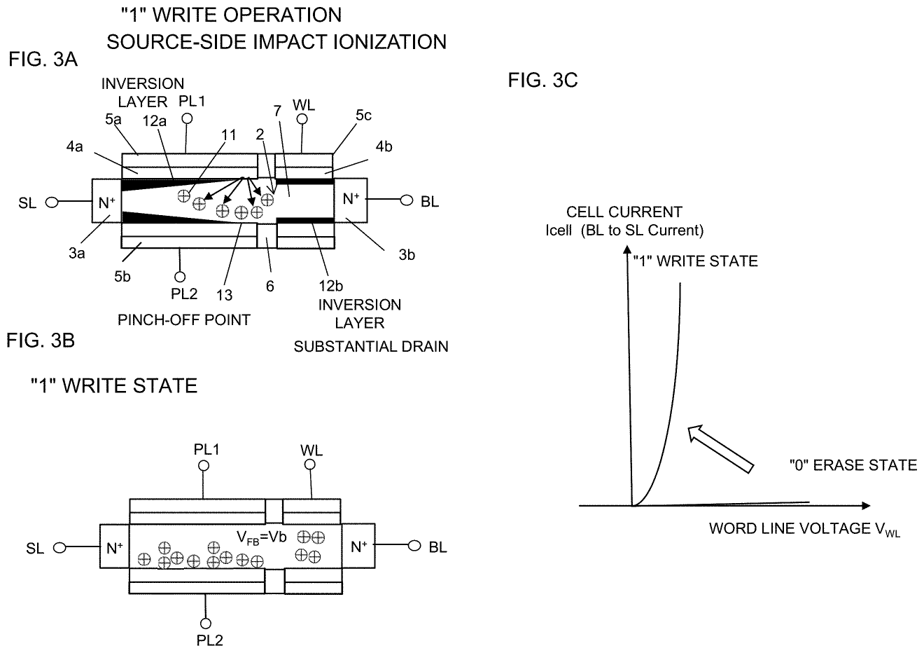

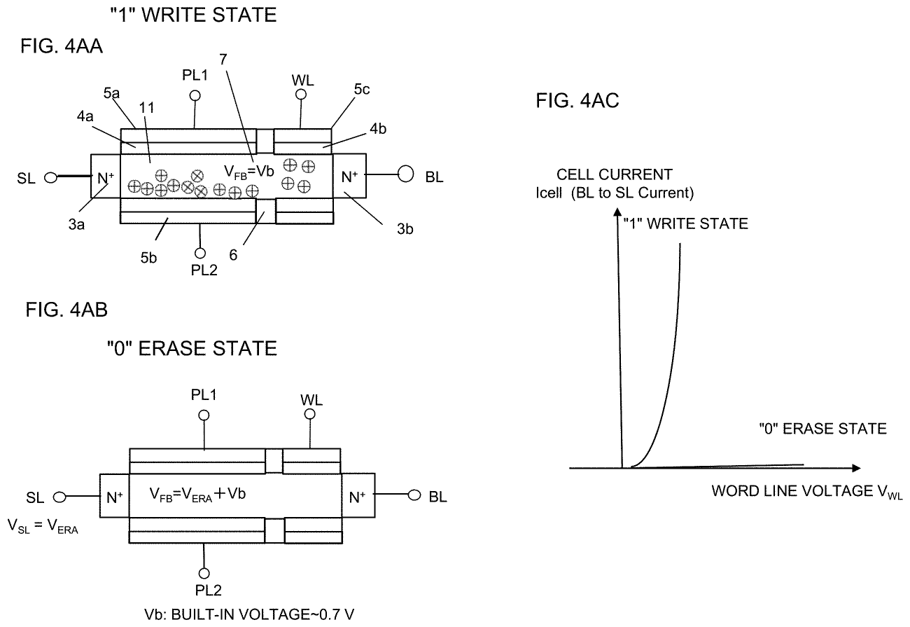

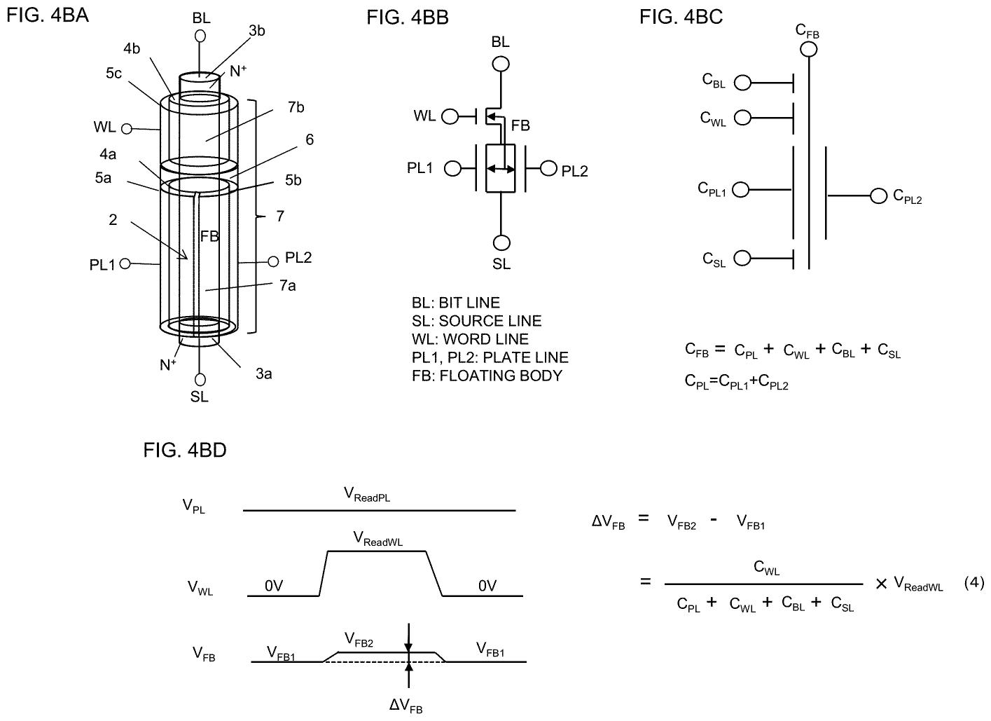

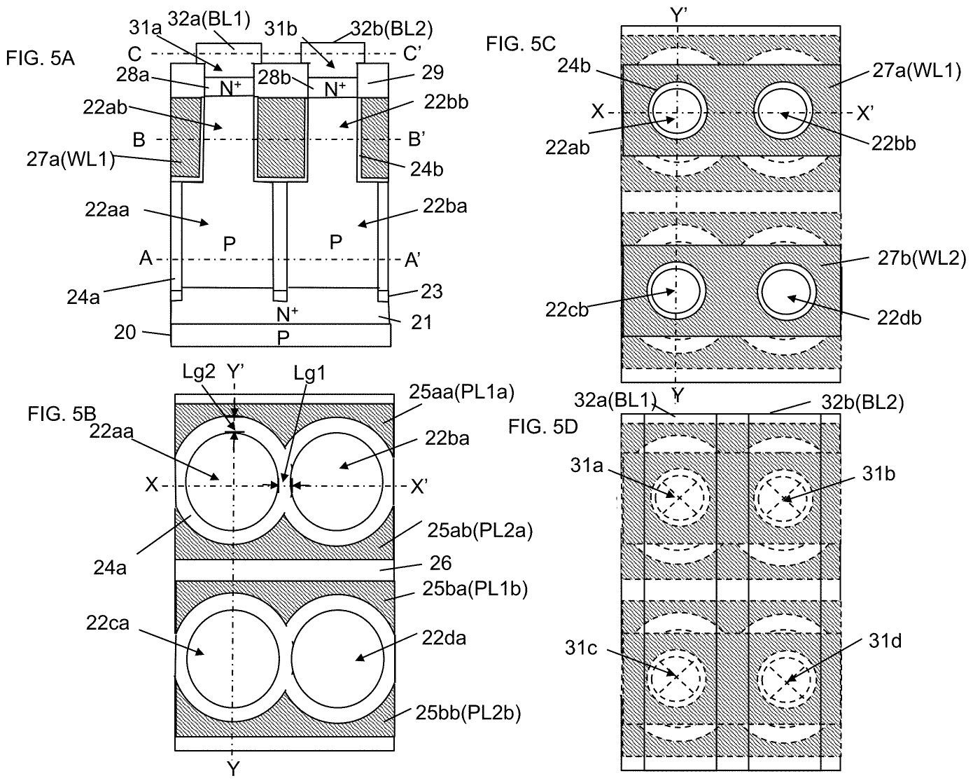

The structure and operation mechanism of a dynamic flash memory cell according to a first embodiment of the present invention will be described with reference to FIGS. 1A to 5D. The structure of the dynamic flash memory cell will be described with reference to FIGS. 1A and 1B. A data erasing mechanism will be described with reference to FIGS. 2A to 2C, a data writing mechanism will be described with reference to FIGS. 3A to 3C, and a data reading mechanism will be described with reference to FIGS. 4AA to 4AC and FIGS. 4BA to 4BD. FIGS. 5A to 5D illustrate a structural diagram of four dynamic flash memory cells formed on a substrate.

FIGS. 1A and 1B illustrate the structure of the dynamic flash memory cell according to the first embodiment of the present invention, in which FIG. 1A is a perspective view and FIG. 1B is a horizontal cross-sectional view of a portion corresponding to first and second gate conductor layers 5a and 5b described below. As illustrated in FIG. 1A, a substrate 1 (an example of “substrate” in the claims) has thereon a silicon pillar 2a (an example of “first semiconductor pillar” in the claims) having a P conductivity type or an i (intrinsic) conductivity type (silicon pillars are hereinafter referred to as “Si pillars”) and a Si pillar 2b (an example of “fifth semiconductor pillar” in the claims) connected to the top of the Si pillar 2a. An N⁺ layer 3a (an example of “first impurity region” in the claims) connected to a bottom portion of the Si pillar 2a, and an N⁺ layer 3b (an example of “second impurity region” in the claims) connected to a top portion of the Si pillar 2b are formed. When one of the N⁺ layer 3a and the N⁺ layer 3b serves as a source, the other serves as a drain. The Si pillars 2a and 2b between the N⁺ layer 3a and the N⁺ layer 3b serve as a channel region 7. A first gate insulating layer 4a (an example of “first gate insulating layer” in the claims) that surrounds the Si pillar 2a, and a second gate insulating layer 4b (an example of “second gate insulating layer” in the claims) that surrounds the Si pillar 2b are formed. The first gate insulating layer 4a and the second gate insulating layer 4b are in contact with or close to the N⁺ layers 3a and 3b serving as the source and the drain, respectively. A first gate conductor layer 5a (an example of “first gate conductor layer” in the claims) and a second gate conductor layer 5b (an example of “second gate conductor layer” in the claims) surround the first gate insulating layer 4a. As illustrated in FIG. 1B, the first gate conductor layer 5a and the second gate conductor layer 5b surround the first gate insulating layer 4a and are formed so as to be separated from each other. Further, an upper gate conductor layer 5c that surrounds the second gate insulating layer 4b is formed. The first gate conductor layer 5a and the upper gate conductor layer 5c are isolated from each other by an insulating layer 6 (an example of “first insulating layer” in the claims), and the second gate conductor layer 5b and the upper gate conductor layer 5c are isolated from each other by the insulating layer 6. The channel region 7 is composed of a first channel region 7a surrounded by the first gate insulating layer 4a, and a second channel region 7b surrounded by the second gate insulating layer 4b. Accordingly, a dynamic flash memory cell 9 composed of the N⁺ layers 3a and 3b serving as the source and the drain, the channel region 7, the first gate insulating layer 4a, the second gate insulating layer 4b, the first gate conductor layer 5a, the second gate conductor layer 5b, and the upper gate conductor layer 5c is formed. The N⁺ layer 3a is connected to a source line SL, the N⁺ layer 3b is connected to a bit line BL, the first gate conductor layer 5a is connected to a first plate line PL1, the second gate conductor layer 5b is connected to a second plate line PL2, and the upper gate conductor layer 5c is connected to a word line WL. In an actual dynamic flash memory device, a plurality of memory cells, each of which is described above, are two-dimensionally arranged on the substrate 1.

The dynamic flash memory cells may be horizontal to the substrate 1. In this case, line K-K′ illustrated in FIG. 1B, which extend through the gaps between opposing ends of the first gate conductor layer 5a and the second gate conductor layer 5b, may be parallel or vertical to the substrate 1. The substrate 1 may be formed of SOI (Silicon On Insulator), single-layer or multi-layer Si, or any other semiconductor material. Alternatively, the substrate 1 may be a well layer composed of a single or multiple N layers or P layers. In FIG. 1B, the first gate conductor layer 5a and the second gate conductor layer 5b that surround the first gate insulating layer 4a have the same circumferential length (outer peripheral length). The first gate conductor layer 5a and the second gate conductor layer 5b may have different outer peripheral lengths.

An erase operation mechanism will be described with reference to FIGS. 2A to 2C. The channel region 7 between the N⁺ layers 3a and 3b is electrically isolated from the substrate 1 and serves as a floating body. FIG. 2A illustrates a state in which a hole group 11 generated by impact ionization in the previous cycle is stored in the channel region 7 before an erase operation is performed. Here, the voltage of the second plate line PL2 is set to be lower than the voltage of the first plate line PL1 to store the hole group 11 in a portion of the channel region 7 adjacent to the second gate conductor layer 5b connected to the second plate line PL2. At the time of the erase operation, as illustrated in FIG. 2B, the voltage of the source line SL is set to a negative voltage V_{ERA}. Here, V_{ERA} is −3 V, for example. As a result, the PN junction between the N⁺ layer 3a serving as the source to which the source line SL is connected and the channel region 7 is forward biased, regardless of the value of an initial potential of the channel region 7. As a result, the hole group 11 stored in the channel region 7, which is generated by impact ionization in the previous cycle, is drawn into the N⁺ layer 3a corresponding to the source portion, and the channel region 7 has a potential V_{FB}, which is given by V_{FB}=V_{ERA}+Vb. Here, Vb is the built-in voltage across the PN junction and is about 0.7 V. When V_{ERA}=−3 V, the potential of the channel region 7 is −2.3 V. This value corresponds to the potential state of the channel region 7 in an erase state. If the potential of the channel region 7 serving as the floating body becomes a negative voltage, the threshold voltage of the N-channel MOS transistor of the dynamic flash memory cell 9 increases due to a substrate bias effect. This increases the threshold voltage of the upper gate conductor layer 5c to which the word line WL is connected, as illustrated in FIG. 2C. The erase state of the channel region 7 corresponds to logical storage data “0”. In data reading, the voltage to be applied to the first gate conductor layer 5a connected to the plate line PL1 is set to be higher than the threshold voltage at the time of logical storage data “1” and lower than the threshold voltage at the time of logical storage data “0”, whereby a characteristic is obtained in which, as illustrated in FIG. 2C, no current flows even when the voltage of the word line WL is increased in reading of the logical storage data “0”. The condition of the voltages to be applied to the bit line BL, the source line SL, the word line WL, and the plate lines PL1 and PL2, described above, is an example for performing the erase operation, and other operation conditions under which the erase operation can be performed may be used. For example, the erase operation may be performed with a voltage difference applied between the bit line BL and the source line SL.

FIGS. 3A to 3C illustrate a write operation of the dynamic flash memory cell according to the first embodiment of the present invention. As illustrated in FIG. 3A, for example, 0 V is input to the N⁺ layer 3a to which the source line SL is connected, for example, 3 V is input to the N⁺ layer 3b to which the bit line BL is connected, for example, 2 V is input to the first gate conductor layer 5a and the second gate conductor layer 5b to which the plate lines PL1 and PL2 are connected, and, for example, 5 V is input to the upper gate conductor layer 5c to which the word line WL is connected. As a result, as illustrated in FIG. 3A, an inversion layer 12a is formed on the inner side of the first gate conductor layer 5a to which the plate line PL1 is connected and the inner side of the second gate conductor layer 5b to which the plate line PL2 is connected, and a first N-channel MOS transistor region composed of the first channel region 7a (see FIGS. 1A and 1B) surrounded by the first gate conductor layer 5a and the second gate conductor layer 5b is operated in a saturation region. This results in generation of pinch-off points 13 in the inversion layer 12a on the inner side of the first gate conductor layer 5a and the second gate conductor layer 5b to which the plate lines PL1 and PL2 are connected. In contrast, a second N-channel MOS transistor region composed of the second channel region 7b (see FIGS. 1A and 1B) surrounded by the upper gate conductor layer 5c to which the word line WL is connected is operated in a linear region. This results in formation of an inversion layer 12b, without any pinch-off point, over the entire inner side of the upper gate conductor layer 5c to which the word line WL is connected. The inversion layer 12b formed over the entire inner side of the upper gate conductor layer 5c to which the word line WL is connected functions as a substantial drain of the first N-channel MOS transistor region including the first gate conductor layer 5a and the second gate conductor layer 5b. As a result, the electric field is maximized in a boundary region (first boundary region) of the channel region 7 between the first N-channel MOS transistor region including the first gate conductor layer 5a and the second gate conductor layer 5b and the second N-channel MOS transistor region including the upper gate conductor layer 5c, which are connected in series, and an impact ionization phenomenon occurs in this region. This region is a source-side region viewed from the second N-channel MOS transistor region including the upper gate conductor layer 5c to which the word line WL is connected, and thus this phenomenon is referred to as a source-side impact ionization phenomenon. The source-side impact ionization phenomenon causes electrons to flow from the N⁺ layer 3a to which the source line SL is connected toward the N⁺ layer 3b to which the bit line BL is connected. The accelerated electrons collide with lattice Si atoms, and the kinetic energy of the collision generates electron-hole pairs. Most of the generated electrons flow to the N⁺ layer 3b to which the bit line BL is connected. In “1” writing, electron-hole pairs may be generated using a gate induced drain leakage (GIDL) current (see NPL 11), and the floating body FB may be filled with the generated hole group. The generation of electron-hole pairs by the impact ionization phenomenon can also be performed near the boundary between the N⁺ layer 3a and the channel region 7 or near the boundary between the N⁺ layer 3b and the channel region 7.

As illustrated in FIG. 3B, the generated hole group 11, which is majority carriers in the channel region 7, charges the channel region 7 to a positive bias. Since the N⁺ layer 3a to which the source line SL is connected is at 0 V, the channel region 7 is charged to the built-in voltage Vb (about 0.7 V) of the PN junction between the N⁺ layer 3a to which the source line SL is connected and the channel region 7. Upon the channel region 7 being charged to a positive bias, the threshold voltages of the first N-channel MOS transistor region and the second N-channel MOS transistor region are decreased due to the substrate bias effect. This results in a decrease in the threshold voltage of the N-channel MOS transistor in the second channel region 7b to which the word line WL is connected, as illustrated in FIG. 3C. The write state of the channel region 7 is assigned to the logical storage data “1”.

At the time of the write operation, electron-hole pairs may be generated by the impact ionization phenomenon or the GIDL current in a second boundary region between a first impurity layer and a first channel semiconductor layer or in a third boundary region between a second impurity layer and a second channel semiconductor layer, instead of the first boundary region, and the channel region 7 may be charged with the generated hole group 11. A voltage for operating in the saturation region may be applied to the first gate conductor layer 5a, and a voltage for operating in the linear region may be applied to the second gate conductor layer 5b and the upper gate conductor layer 5c. In this case, the impact ionization phenomenon occurs in a portion of the surface layer of the channel region 7 adjacent to the first gate conductor layer 5a. The condition of the voltages to be applied to the bit line BL, the source line SL, the word line WL, and the plate lines PL1 and PL2, described above, is an example for performing the write operation, and other operation conditions under which the write operation can be performed may be used.

A read operation of the dynamic flash memory cell according to the first embodiment of the present invention and a memory cell structure related thereto will be described with reference to FIGS. 4AA to 4AC and FIG. 4BA to 4BD. The read operation of the dynamic flash memory cell will be described with reference to FIG. 4AA to FIG. 4AC. As illustrated in FIG. 4AA, upon the channel region 7 being charged to the built-in voltage Vb (about 0.7 V), the threshold voltage of the N-channel MOS transistor is decreased due to the substrate bias effect. This state is assigned to the logical storage data “1”. As illustrated in FIG. 4AB, when the memory block to be selected before writing is performed is in the erase state “0” in advance, the channel region 7 is at a floating voltage V_{FB}, which is given by V_{ERA}+Vb. Through the write operation, the write state “1” is stored randomly. As a result, logical storage data of logic “0” and “1” is created for the word line WL. As illustrated in FIG. 4AC, the difference between the two threshold voltages for the word line WL is used to perform reading by using a sense amplifier. In data reading, the voltage to be applied to the first gate conductor layer 5a connected to the plate line PL1 is set to be higher than the threshold voltage at the time of logical storage data “1” and lower than the threshold voltage at the time of logical storage data “0”, whereby a characteristic is obtained in which, as illustrated in FIG. 4AC, no current flows even when the voltage of the word line WL is increased in reading of the logical storage data “0”. In data reading, the voltages to be applied to the plate lines PL1 and PL2 may be controlled to extract a read cell current from both surface layer channels of the channel region 7 surrounded by the first gate conductor layer 5a and the second gate conductor layer 5b. As a result, a large read cell current can be obtained. In this case, it is desirable to control the voltages to be applied to the bit line BL, the source line SL, the word line WL, and the plate lines PL1 and PL2 in the logic “1” read operation to generate the impact ionization phenomenon in the channel region 7 to perform the rewriting of logic “1”.

Referring to FIG. 4BA to FIG. 4BD, a description will be given of the magnitude relationship of the gate capacitance among the three gate conductor layers, namely, the first gate conductor layer 5a, the second gate conductor layer 5b, and the upper gate conductor layer 5c, at the time of the read operation of the dynamic flash memory cell according to the first embodiment of the present invention, and the operation related thereto. The gate capacitance of the upper gate conductor layer 5c to which the word line WL is connected is desirably designed to be smaller than the gate capacitance obtained by totaling the capacitance of the first gate conductor layer 5a and the capacitance of the second gate conductor layer 5b to which the plate lines PL1 and PL2 are connected. As illustrated in FIG. 4BA, the vertical lengths of the first gate conductor layer 5a and the second gate conductor layer 5b to which the plate lines PL1 and PL2 are connected are set to be longer than the vertical length of the upper gate conductor layer 5c to which the word line WL is connected to make the gate capacitance of the upper gate conductor layer 5c to which the word line WL is connected smaller than the gate capacitance obtained by totaling the capacitances of the first gate conductor layer 5a and the second gate conductor layer 5b to which the plate lines PL1 and PL2 are connected. FIG. 4BB illustrates an equivalent circuit of one cell of the dynamic flash memory illustrated in FIG. 4BA. FIG. 4BC illustrates a coupling capacitance relationship of the dynamic flash memory. Here, C_{WL} is the capacitance of the upper gate conductor layer 5c, C_{PL} is the capacitance obtained by totaling the capacitance C_{PL1} of the first gate conductor layer 5a and the capacitance C_{PL2} of the second gate conductor layer 5b, C_{BL} is the capacitance of the PN junction between the N⁺ layer 3b serving as the drain and the second channel region 7b, and C_{SL} is the capacitance of the PN junction between the N⁺ layer 3a serving as the source and the first channel region 7a. As illustrated in FIG. 4BD, an oscillation of the voltage of the word line WL affects the channel region 7 as noise. A potential variation ΔV_{FB} of the channel region 7 at this time is expressed by the following equation.

ΔV_{FB}=C_{WL}/(C_{PL}+C_{WL}+C_{BL}+C_{SL})×V_{ReadWL} (4)

Here, V_{ReadWL} is the oscillating potential of the word line WL at the time of reading. As is apparent from equation (4), a reduction in the contribution ratio of C_{WL} compared with the total capacitance C_{PL}+C_{WL}+C_{BL}+C_{SL} of the channel region 7 decreases ΔV_{FB}. C_{BL}+C_{SL} is the capacitance of the PN junction, and is increased by, for example, increasing the diameters of the Si pillar 2. However, this is not desirable for the miniaturization of the memory cell. In contrast, the lengths of the first gate conductor layer 5a and the second gate conductor layer 5b, which are connected to the plate lines PL1 and PL2, in the axial direction are set to be longer than the length of the upper gate conductor layer 5c, to which the word line WL is connected, in the axial direction, whereby ΔV_{FB} can be further reduced without reducing the degree of integration of memory cells in plan view. The condition of the voltages to be applied to the bit line BL, the source line SL, the word line WL, and the plate lines PL1 and PL2, described above, is an example for performing the read operation, and other operation conditions under which the read operation can be performed may be used.

FIGS. 5A to 5D illustrate a structural diagram of a memory device in which four dynamic flash memory cells according to this embodiment are formed on a substrate 20. FIG. 5A is a vertical cross-sectional view taken along line X-X′ of FIG. 5B. FIG. 5B is a horizontal cross-sectional view taken along line A-A′ of FIG. 5A. FIG. 5C is a horizontal cross-sectional view taken along line B-B′ of FIG. 5A. FIG. 5D is a horizontal cross-sectional view taken along line C-C′ of FIG. 5A. In an actual memory device, more than four dynamic flash memory cells are arranged in rows and columns.

As illustrated in FIGS. 5A to 5D, the substrate 20 has thereon an N⁺ layer 21 (an example of “first impurity region” in the claims). First Si pillars 22aa (an example of “first semiconductor pillar”), 22ba (an example of “second semiconductor pillar”), 22ca (an example of “third semiconductor pillar”), and 22da (an example of “fourth semiconductor pillar”) stand on the N⁺ layer 21. Second Si pillars 22ab (an example of “fifth semiconductor pillar”), 22bb (an example of “sixth semiconductor pillar”), 22cb (an example of “seventh semiconductor pillar”), and 22db (an example of “eighth semiconductor pillar”) stand on the first Si pillars 22aa to 22da. In plan view, the outer peripheral edges of the second Si pillars 22ab to 22db are inside the outer peripheral edges of the first Si pillars 22aa to 22da. The second Si pillars 22ab to 22db have in top portions thereof N⁺ layers 28a, 28b, 28c (not illustrated), and 28d (not illustrated) (an example of “second impurity region” in the claims), respectively. The N⁺ layer 21 further has thereon SiO₂ layers 23 surrounding bottom portions of the Si pillars 22aa to 22da. HfO₂ layers 24a (an example of “first gate insulating layer” in the claims) surround lower side surfaces of the Si pillars 22aa to 22da. In plan view, the HfO₂ layers 24a are formed to be connected to each other between the Si pillars 22aa and 22ba, which are adjacent to each other in the line X-X′ direction. Likewise, the HfO₂ layers 24a are formed to be connected to each other between the Si pillars 22ca and 22da. Separate TiN layers 25aa (an example of “first gate conductor layer” in the claims) and 25ab (an example of “second gate conductor layer” in the claims), which surround the HfO₂ layers 24a on the side surfaces of the Si pillars 22aa and 22ba and are each continuous in the line X-X′ direction, are formed so as to be separated from each other by the HfO₂ layers 24a. Likewise, separate TiN layers 25ba (an example of “third gate conductor layer” in the claims) and 25bb (an example of “fourth gate conductor layer” in the claims), which surround the HfO₂ layers 24a on the side surfaces of the Si pillars 22ca and 22da and are each continuous in a direction parallel to the line X-X′, are formed. A SiO₂ layer 26 is located between the TiN layers 25ab and 25ba.

HfO₂ layers 24b (an example of “second gate insulating layer” in the claims) surround side surfaces of the Si pillars 22ab to 22db and are connected to the HfO₂ layers 24a. A TiN layer 27a (an example of “fifth gate conductor layer” in the claims) surrounds the HfO₂ layers 24b on the side surfaces of the Si pillars 22ab and 22bb and is continuous in the line X-X′ direction. Likewise, a TiN layer 27b (an example of “sixth gate conductor layer” in the claims) surrounds the HfO₂ layers 24b on the side surfaces of the Si pillars 22cb and 22db and is continuous in a direction parallel to the line X-X′. The TiN layer 27b is separated from the TiN layer 27a. A SiO₂ layer 29 surrounds the TiN layers 27a and 27b and the N⁺ layers 28a to 28d. The SiO₂ layer 29 on the N⁺ layers 28a to 28d has contact holes 31a, 31b, 31c, and 31d. Further, a metal wiring layer 32a (an example of “first wiring conductor layer” in the claims) is connected to the N⁺ layers 28a and 28c via the contact holes 31a and 31c and extends in a direction perpendicular to the line X-X′, and a metal wiring layer 32b (an example of “second wiring conductor layer” in the claims) is connected to the N⁺ layers 28b and 28d via the contact holes 31b and 31d and extends in the direction perpendicular to the line X-X′.

In FIGS. 5A to 5D, the N⁺ layer 21 is connected to the source line SL described with reference to FIGS. 1A and 1B, the TiN layers 25aa and 25ba are connected to plate lines PL1a and PL1b, which correspond to the plate line PL1 described with reference to FIGS. 1A and 1B, and the TiN layers 25ab and 25bb are connected to plate lines PL2a and PL2b, which correspond to the plate line PL2 described with reference to FIGS. 1A and 1B. The TiN layers 27a and 27b are connected to word lines WL1 and WL2, which correspond to the word line WL described with reference to FIGS. 1A and 1B, and the metal wiring layers 32a and 32b are connected to bit lines BL1 and BL2, which correspond to the bit line BL described with reference to FIGS. 1A and 1B.

The HfO₂ layers 24a have a required thickness that is determined from the setting of the threshold voltage required for MOS (Metal Oxide Semiconductor) transistor operation and from the requirement of the processing margin to be required. When the Si pillars 22aa to 22da illustrated in FIG. 5B are formed sufficiently apart from each other and the HfO₂ layers 24a are formed so as to surround the Si pillars 22aa to 22da and have an equal width with a length Lg2 (an example of “second length” in the claims) in plan view, as illustrated in FIG. 5B, a length Lg1 (an example of “first length” in the claims) of the HfO₂ layers 24a surrounding the Si pillars 22aa and 22ba and facing each other along the line X-X′ is set to be shorter than twice the length Lg2 or equal to or larger than the length width Lg2. Accordingly, only the HfO₂ layers 24a are formed between the Si pillars 22aa and 22ba along the line X-X′. In the line Y-Y′ direction perpendicular to the line X-X′, the HfO₂ layers 24a surrounding the Si pillars 22aa and 22ca and facing each other are formed such that the outer peripheral ends of the HfO₂ layers 24a are spaced apart from each other. As a result, the TiN layers 25aa, 25ab, 25ba, and 25bb, each of which is continuous in the line X-X′ direction, are formed so as to be separated from each other in the line Y-Y′ direction.

The HfO₂ layers 24a and 24b may be formed of material layers serving as a gate insulating layer, each of which is composed of a single layer or multiple layers. Alternatively, the HfO₂ layers 24a may be formed of a different material layer and have a different thickness and the like from the HfO₂ layers 24b.

In FIGS. 5A to 5D, the outer peripheral edges of the second Si pillars 22ab to 22db are formed to be inside the outer peripheral edges of the first Si pillars 22aa to 22da in plan view. Further, the HfO₂ layers 24b surrounding the second Si pillars 22ab to 22db and serving as the respective gate insulating layers are formed so as not to overlap each other in plan view. Accordingly, the TiN layers 27a and 27b surrounding the entire outer periphery of the second Si pillars 22ab to 22db are formed. This is to improve the switching characteristics of word transistors connected to the word lines WL1 and WL2. Alternatively, in plan view in FIG. 5C, the HfO₂ layers 24b between the second Si pillars 22ab and 22bb may be connected to each other, and the HfO₂ layers 24b between the Si pillars 22cb and 22db may be connected to each other. In this case, in plan view, the two separated TiN layers 27a are connected to each other and driven as the word line WL1. The same applies to the TiN layers 27b.

In FIGS. 1A and 1B, the N⁺ layers 3a and 3b and the Si pillar 2 in which the channel region 7 is of the P-type are used. Alternatively, the N⁺ layers 3a and 3b may be replaced with P⁺ layers, and the Si pillar 2 may be replaced with an N layer instead of a P layer. In this case, the following operations are performed: an operation of generating an electron group and a hole group by the impact ionization phenomenon or the gate induced drain leakage current and removing, of the generated electron group and hole group, the hole group as minority carriers in the N-layer channel region from the P⁺ layer of one or both of the source and the drain; a memory write operation of causing a part or the whole of the electron group as majority carriers in the N-layer channel region to remain left in the Si pillar 2; and a memory erase operation of extracting the left electrons out of the electron group from one or both of the P⁺ layers of the source and the drain. Through the operations described above, a dynamic flash memory operation can also be performed. This also applies to the other embodiments.

Further, in FIGS. 1A and 1B, even if the upper gate conductor layer 5c surrounds part of the second gate insulating layer 4b, the dynamic flash memory operation can be perform. The upper gate conductor layer 5c may be divided into a plurality of conductor layers and operated.

In FIGS. 1A and 1B, the first gate conductor layer 5a connected to the first plate line PL1 and the second gate conductor layer 5b connected to the second plate line PL2 are disposed adjacent to the N⁺ layer 3a connected to the source line SL. Alternatively, the upper gate conductor layer 5c connected to the word line WL may be disposed adjacent to the N⁺ layer 3a, and the first gate conductor layer 5a and the second gate conductor layer 5b may be disposed adjacent to the N⁺ layer 3b connected to the bit line BL. In this case, the upper gate conductor layer 5c may be divided into two portions in a manner similar to that of the first gate conductor layer 5a and the second gate conductor layer 5b. In FIGS. 5A to 5D, furthermore, the outer periphery of the Si pillars 22ab to 22db is formed to be inside the outer periphery of the Si pillars 22aa to 22da in plan view, and the TiN layer 27a is formed between the Si pillars 22ab and 22bb along the line X-X′. Alternatively, in plan view, the outer periphery of the Si pillars 22ab to 22db may be formed to be substantially the same as that of the Si pillars 22aa to 22da such that the HfO₂ layer 24b is formed between the Si pillars 22ab and 22bb along the line X-X′. In this case, the TiN layers 27a and 27b are each separated into two portions.

This embodiment provides the following features.

### (Feature 1)

In the dynamic flash memory cell according to the first embodiment of the present invention, the voltage of the word line WL oscillates up and down in a write or read operation. At this time, the first gate conductor layer 5a and the second gate conductor layer 5b, which are connected to the plate lines PL1 and PL2, function to reduce the capacitive coupling ratio between the word line WL and the channel region 7. This results in a significant reduction in the influence of the change in voltage across the channel region 7 caused by the up and down oscillation of the voltage of the word line WL. Accordingly, the difference between the threshold voltages of an SGT transistor on the word line WL that indicate logic “0” and logic “1” can be increased. This leads to an increase in the operation margin of the dynamic flash memory cell.

### (Feature 2)

In the first embodiment of the present invention, the first gate conductor layer 5a connected to the plate line PL1 and the second gate conductor layer 5b connected to the plate line PL2 are separately formed so as to surround the first gate insulating layer 4a. The voltage to be applied to the plate line PL2 is set to be lower than the voltage to be applied to the plate line PL1, which allows the hole group to be accumulated in a portion of the first channel region 7a adjacent to the second gate conductor layer 5b connected to the plate line PL2. This makes it possible to accumulate a larger number of holes than in a structure in which the entire first channel region 7a is surrounded by one gate electrode. In the read operation, the floating body voltage in the first channel region 7a can be controlled by the voltage to be applied to the second gate conductor layer 5b. This makes it possible to maintain a more stable back-bias effect in the read operation. Accordingly, a dynamic flash memory cell having a wider operation margin can be achieved.

### (Feature 3)

As illustrated in FIG. 5B, in plan view, the HfO₂ layers 24a, which are gate insulating layers, lie between the Si pillars 22aa and 22ba and the space between the Si pillars 22ca and 22da along the line X-X′. As a result, the TiN layers 25aa and 25ab, which are continuous across the Si pillars 22aa and 22ba in the line X-X′ direction, are formed so as to be separated from each other. Likewise, the TiN layers 25ba and 25bb, which are continuous across the Si pillars 22ca and 22da, are formed so as to be separated from each other. The TiN layers 25ab and 25ba are formed so as to be separated from each other. Accordingly, a dynamic flash memory is formed in which the TiN layers 25aa and 25ba serve as the first gate conductor layer 5a connected to the plate line PL1 in FIGS. 1A and 1B and the TiN layers 25ab and 25bb serve as the second gate conductor layer 5b connected to the plate line PL2. This leads to realization of a dynamic flash memory cell having a wider operation margin.

### (Feature 4)

As illustrated in FIGS. 5A to 5D, the outer peripheral edges of the second Si pillars 22ab to 22db are formed to be inside the outer peripheral edges of the first Si pillars 22aa to 22da in plan view. Further, the HfO₂ layers 24b surrounding the second Si pillars 22ab to 22db and serving as the respective gate insulating layers are formed so as not to overlap each other in plan view. Accordingly, the TiN layers 27a and 27b surrounding the entire second Si pillars 22ab to 22db are formed. This can improve the switching characteristics of word transistors connected to the word lines WL1 and WL2.

### (Feature 5)

For example, in an operation of applying a pulse voltage to the word line WL1 and the plate line PL1a to perform reading of a memory cell connected to the word line WL1, fixing the voltages to be applied to the plate lines PL2a and PL2b can reduce the capacitive coupling noise between the plate lines PL1a and PL1b. This can increase the operation margin of the dynamic flash memory cell.

### Second Embodiment

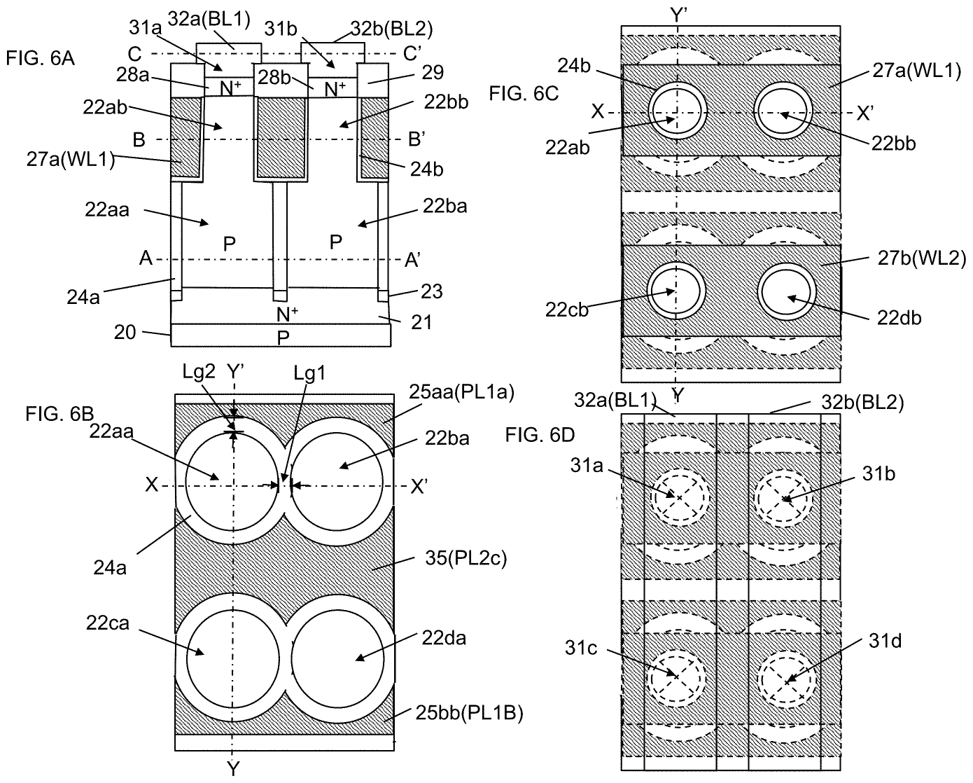

The structure of memory cells of a dynamic flash memory device according to a second embodiment will be described with reference to FIGS. 6A to 6D. FIG. 6A is a vertical cross-sectional view of the dynamic flash memory device taken along line X-X′ of FIG. 6B. FIG. 6B is a horizontal cross-sectional view taken along line A-A′ of FIG. 6A. FIG. 6C is a horizontal cross-sectional view taken along line B-B′ of FIG. 6A. FIG. 6D is a horizontal cross-sectional view taken along line C-C′ of FIG. 6A. In FIGS. 6A to 6D, the same components as those in FIGS. 5A to 5D are denoted by the same reference numerals.

As illustrated in FIG. 6B, the TiN layers 25ab and 25ba, which are separated from each other in FIGS. 5A to 5D, are connected to each other to form a TiN layer 35. The other components are the same as those illustrated in FIGS. 5A to 5D. The TiN layers 25aa and 25bb are connected to the plate lines PL1a and PL1B, which correspond to the plate line PL1 described with reference to FIGS. 1A and 1B, and the TiN layer 35 is connected to a plate line PL2c, which corresponds to the plate line PL2 described with reference to FIGS. 1A and 1B. In this case, the hole group is accumulated in portions of the Si pillars 22aa to 22da adjacent to the TiN layer 35.

This embodiment provides the following features.

As illustrated in FIGS. 6A to 6D, the TiN layers 25ab and 25ba, which are separated from each other in FIGS. 5A to 5D, are connected to each other into the TiN layer 35. This can reduce the distances between the cells of the dynamic flash memory in the line Y-Y′ direction. As a result, a high-integration dynamic flash memory can be achieved.

### Third Embodiment

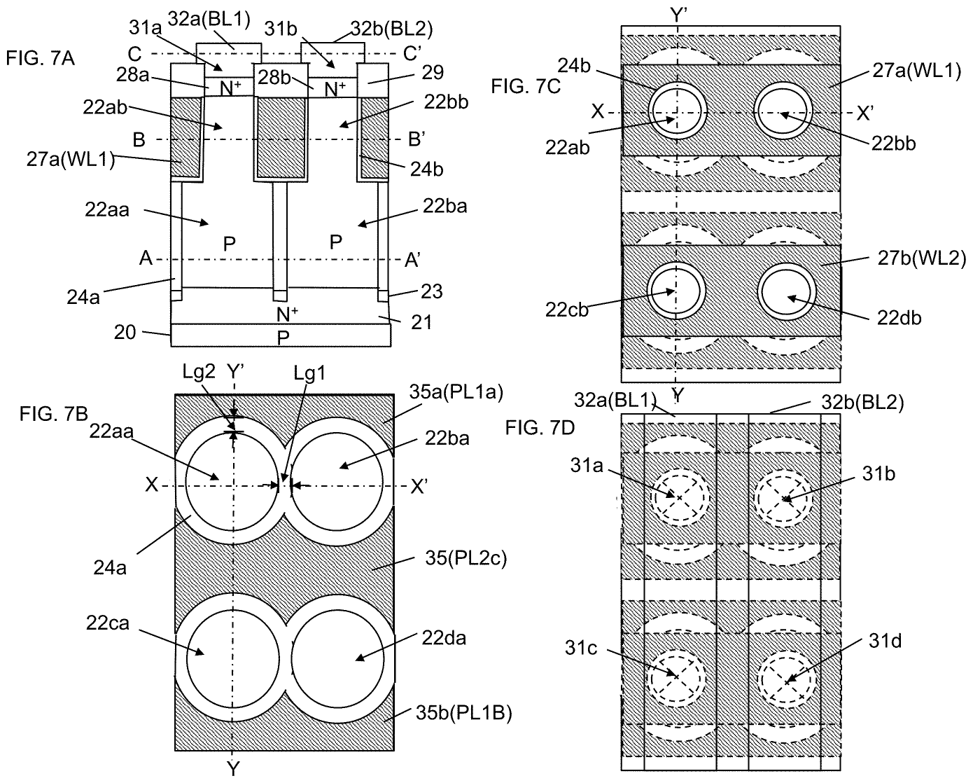

The structure of memory cells of a dynamic flash memory device according to a third embodiment will be described with reference to FIGS. 7A to 7D. FIG. 7A is a vertical cross-sectional view of the dynamic flash memory device taken along line X-X′ of FIG. 7B. FIG. 7B is a horizontal cross-sectional view taken along line A-A′ of FIG. 7A. FIG. 7C is a cross-sectional plan view taken along line B-B′ of FIG. 7A. FIG. 7D is a horizontal cross-sectional view taken along line C-C′ of FIG. 7A. In FIGS. 7A to 7D, the same components as those in FIGS. 6A to 6D are denoted by the same reference numerals.

In the second embodiment described above, as illustrated in FIG. 6B, the TiN layer 25aa connected to the plate line PL1a is separated from a TiN layer (not illustrated) connected to a plate line located above the TiN layer 25aa in the line Y-Y′ direction. Likewise, the TiN layer 25bb connected to the plate line PL1B is separated from a TiN layer (not illustrated) connected to a plate line located below the TiN layer 25bb in the line Y-Y′ direction. In this embodiment, in contrast, as illustrated in FIG. 7B, the TiN layer 25aa and the TiN layer (not illustrated) located above the TiN layer 25aa, which are separated from each other in FIGS. 6A to 6D, are connected to each other to form a TiN layer 35a, and the TiN layer 25bb and the TiN layer (not illustrated) located below the TiN layer 25bb, which are separated from each other in FIGS. 6A to 6D, are connected to each other to form a TiN layer 35b. The other components are the same as those illustrated in FIGS. 6A to 6D. The TiN layers 25aa and 25bb are connected to the plate lines PL1a and PL1B, which correspond to the plate line PL1 described with reference to FIGS. 1A and 1B. The TiN layer 35 is connected to a plate line PL2c, which corresponds to the plate line PL2 described with reference to FIGS. 1A and 1B. In this case, the hole group is accumulated in portions of the Si pillars 22aa to 22da adjacent to the TiN layer 35.

This embodiment provides the following features.

As illustrated in FIGS. 7A to 7D, the TiN layers 25aa and 25bb are connected to the TiN layers located above and below the TiN layers 25aa and 25bb in the line Y-Y′ direction in plan view, the TiN layers 25aa and 25bb being separated from the respective TiN layers in FIGS. 6A to 6D, to form the TiN layers 35a and 35b. This can further reduce the distances between the cells of the dynamic flash memory in the line Y-Y′ direction compared with FIGS. 6A to 6D. As a result, a high-integration dynamic flash memory can be achieved.

### OTHER EMBODIMENTS

While the Si pillar 2 is formed in the first embodiment, a semiconductor pillar composed of any other semiconductor material may be used. The same applies to the other embodiments according to the present invention.

In the first embodiment, the N⁺ layers 3a and 3b may be formed of layers made of Si containing a donor impurity or any other semiconductor material. The N⁺ layers 3a and 3b may be formed by layers made of different semiconductor materials. The N⁺ layers may be formed by epitaxial crystal growth or any other method. The same applies to the other embodiments according to the present invention.

In FIGS. 5A to 5D, the TiN layers 25aa, 25ab, 25ba, and 25bb are used as gate conductor layers connected to the plate lines PLa1, PLa2, PLb1, and PLb2. Alternatively, a single conductor material layer or a combination of multiple conductor material layers may be used in place of the TiN layers 25aa, 25ab, 25ba, and 25bb. Likewise, the TiN layers 27a and 27b are used as gate conductor layers connected to the word lines WL1 and WL2. Alternatively, a single conductor material layer or a combination of multiple conductor material layers may be used in place of the TiN layers 27a and 27b. The outer sides of the gate TiN layers 25aa, 25ab, 25ba, 25bb, 27a, and 27b may be connected to wiring metal layers such as W. The same applies to the other embodiments according to the present invention.

In FIGS. 5A to 5D, the TiN layers 25aa to 25bb, 27a, and 27b may be each constituted by two layers, namely, a TiN layer and a TaN layer, for example. Alternatively, the TiN layers 25aa to 25bb, 27a, and 27b may be each formed of a first layer serving as a gate conductor layer and a second layer serving as a protective film. The same applies to the other embodiments according to the present invention. Alternatively, low-resistance doped poly-Si may be used in place of the TiN layers 25aa, 25ab, 25ba, and 25bb, and the upper surfaces thereof may be oxidized to produce SiO₂ layers to form interlayer insulating layers between gate conductor layers (corresponding to the TiN layers 25aa, 25ab, 25ba, and 25bb) and the TiN layers 27a and 27b. In this case, two layers, namely, a thin TiN layer and a thick low-resistance doped poly-Si layer, may be used as a gate conductor layer. The same applies to other embodiments according to the present invention.

In FIGS. 5A to 5D, an example is presented in which the four Si pillars 22aa to 22da are formed on the substrate 20. However, four or more Si pillars may be formed. The same applies to the other embodiments according to the present invention.

In FIGS. 1A and 1B, the Si pillar 2 has a circular shape in plan view. Alternatively, the shape of the Si pillar 2 in plan view may be an ellipse, a shape elongated in one direction, or the like. Si pillars having different shapes in plan view can be combined to form a dynamic flash memory cell. The same applies to other embodiments according to the present invention.

In FIGS. 1A and 1B, the Si pillars 2a and 2b having a rectangular vertical cross section are used. However, the vertical cross section of the Si pillars 2a and 2b may be trapezoidal. Alternatively, of the Si pillar 2 of the dynamic flash memory cell, the cross section of the Si pillar 2a surrounded by the first gate insulating layer 4a and the cross section of the Si pillar 2b surrounded by the second gate insulating layer 4b may have different shapes such as a rectangular shape and a trapezoidal shape. The same applies to the other embodiments according to the present invention.

In FIGS. 5A to 5D, furthermore, a conductor layer such as a W layer may be connected to the N⁺ layer 21 at the bottom portions of the Si pillars 22aa to 22da. The same applies to the other embodiments according to the present invention.

In FIGS. 1A and 1B, the gate lengths of the first gate conductor layer 5a and the second gate conductor layer 5b are set to be longer than the gate length of the upper gate conductor layer 5c so that the gate capacitances of the first gate conductor layer 5a and the second gate conductor layer 5b connected to the plate lines PL1 and PL2 are larger than the gate capacitance of the upper gate conductor layer 5c connected to the word line WL. As a result, the gate capacitance obtained by totaling the gate capacitance of the first gate conductor layer 5a and the gate capacitance of the second gate conductor layer 5b can be larger than the gate capacitance of the upper gate conductor layer 5c. In addition, also in a structure in which the gate lengths of the first gate conductor layer 5a and the second gate conductor layer 5b are set to be longer or not longer than the gate length of the upper gate conductor layer 5c, for example, the thickness of the gate insulating film of the first gate insulating layer 4a is set to be thinner than the thickness of the gate insulating film of the second gate insulating layer 4b, whereby the gate capacitance obtained by totaling the gate capacitance of the first gate conductor layer 5a and the gate capacitance of the second gate conductor layer 5b can be larger than the gate capacitance of the upper gate conductor layer 5c. The dielectric constant of the gate insulating film of the first gate insulating layer 4a may be set to be higher than the dielectric constant of the gate insulating film of the second gate insulating layer 4b by changing the dielectric constants of the materials of the respective gate insulating layers. Further, any of the lengths of the gate conductor layers 5a, 5b, and 5c, the thicknesses of the gate insulating layers 4a and 4b, and the dielectric constants of the gate insulating layers 4a and 4b may be combined so that the gate capacitance obtained by totaling the gate capacitance of the first gate conductor layer 5a and the gate capacitance of the second gate conductor layer 5b can be larger than the gate capacitance of the upper gate conductor layer 5c. The same applies to the other embodiments according to the present invention.

While FIGS. 5A to 5D illustrate an example in which the Si pillars 22aa to 22da are arranged in a square lattice shape in plan view, the Si pillars 22aa to 22da may be arranged in an oblique lattice shape, or in a zigzag shape or a saw-tooth shape when the Si pillars 22aa to 22da are four or more Si pillars. The same applies to the other embodiments according to the present invention.

In FIGS. 5A to 5D, furthermore, the bottom N⁺ layer 21 connected to the source line SL is continuous at the bottom portions of the Si pillars 22aa to 22da. Alternatively, in plan view, the bottom N⁺ layer connected to the source line SL may be formed such that the N⁺ layer connected to the bottom portions of the Si pillars 22aa and 22ba and the N⁺ layer connected to the bottom portions of the Si pillars 22ca and 22da are electrically isolated from each other. The electrical isolation between the N⁺ layers connected to the source line SL is implemented by a well structure or SOI, for example. This enables independent driving of the source line connected to the N⁺ layer at the bottom portions of the Si pillars 22aa and 22ba and the source line SL connected to the N⁺ layer at the bottom portions of the Si pillars 22ca and 22da. In this case, it is desirable to provide a conductor layer made of metal, an alloy, or the like, which is connected to the isolated N⁺ layers. The same applies to the other embodiments according to the present invention.

In FIGS. 1A and 1B, the first gate conductor layer 5a connected to the first plate line PL1 and the second gate conductor layer 5b connected to the second plate line PL2 are disposed adjacent to the N⁺ layer 3a connected to the source line SL. Alternatively, the upper gate conductor layer 5c connected to the word line WL may be disposed adjacent to the N⁺ layer 3a, and the first gate conductor layer 5a and the second gate conductor layer 5b may be disposed adjacent to the N⁺ layer 3b connected to the bit line BL. The same applies to the other embodiments according to the present invention.

Various embodiments and modifications can be made to the present invention without departing from the broad spirit and scope of the present invention. The embodiments described above are for explaining an example of the present invention, and do not limit the scope of the present invention. The embodiments and modifications described above can be combined as desired. Some of the components may be removed as necessary from the embodiments described above to form other embodiments within scope of the technical idea of the present invention.

### INDUSTRIAL APPLICABILITY

A memory device using a pillar-shaped semiconductor element according to the present invention can achieve a semiconductor device including a high-density and high-performance dynamic flash memory.

1. A memory device using a pillar-shaped semiconductor element, comprising:
a first semiconductor pillar, a second semiconductor pillar, a third semiconductor pillar, and a fourth semiconductor pillar standing on a substrate in a vertical direction to the substrate, the first semiconductor pillar and the second semiconductor pillar having center points on a first straight line in plan view and being arranged adjacent to each other, the third semiconductor pillar and the fourth semiconductor pillar having center points on a second straight line parallel to the first line in plan view and being arranged adjacent to each other;
a first impurity region connected to bottom portions of the first to fourth semiconductor pillars;
first gate insulating layers positioned above the first impurity region in the vertical direction and each surrounding a side surface of a corresponding one of the first to fourth semiconductor pillars;
a first gate conductor layer and a second gate conductor layer surrounding the respective first gate insulating layers of the first semiconductor pillar and the second semiconductor pillar in plan view and each extending to be continuous along the first straight line, the first gate conductor layer and the second gate conductor layer being separated from each other in plan view;
a third gate conductor layer and a fourth gate conductor layer surrounding the respective first gate insulating layers of the third semiconductor pillar and the fourth semiconductor pillar in plan view and each extending to be continuous along the second straight line, the third gate conductor layer and the fourth gate conductor layer being separated from each other in plan view;
fifth to eighth semiconductor pillars positioned on top of the first to fourth semiconductor pillars, respectively;
second gate insulating layers positioned above the first gate insulating layers in the vertical direction and each surrounding a side surface of a corresponding one of the fifth to eighth semiconductor pillars;
a fifth gate conductor layer and a sixth gate conductor layer surrounding the second gate insulating layers and having upper surfaces positioned below top portions of the fifth to eighth semiconductor pillars, the fifth gate conductor layer and the sixth gate conductor layer being separated from the first to fourth gate conductor layers in the vertical direction, the fifth gate conductor layer surrounding the fifth semiconductor pillar and the sixth semiconductor pillar and extending to be continuous along the first straight line, the sixth gate conductor layer surrounding the seventh semiconductor pillar and the eighth semiconductor pillar and extending to be continuous along the second straight line;
second impurity regions each positioned at the top portion of a corresponding one of the fifth to eighth semiconductor pillars;
a first wiring conductor layer connected to the second impurity region at the top portion of the fifth semiconductor pillar and the second impurity region at the top portion of the seventh semiconductor pillar; and
a second wiring conductor layer connected to the second impurity region at the top portion of the sixth semiconductor pillar and the second impurity region at the top portion of the eighth semiconductor pillar, wherein
in plan view, the first gate insulating layers lie between two opposing intersections among intersections between the first straight line and two outer peripheral edges of the first semiconductor pillar and the second semiconductor pillar, and the first gate insulating layers lie between two opposing intersections among intersections between the second straight line and two outer peripheral edges of the third semiconductor pillar and the fourth semiconductor pillar, and
the memory device is configured to control a voltage to be applied to the first to sixth gate conductor layers, a voltage to be applied to the first impurity region, and a voltage to be applied to the second impurity regions to perform a data write operation, a data read operation, and a data erase operation.

2. The memory device using a pillar-shaped semiconductor element according to claim 1, wherein in plan view, a first length between the two opposing intersections among the intersections between the first straight line and the two outer peripheral edges of the first semiconductor pillar and the second semiconductor pillar is smaller than twice a second length and is greater than or equal to the second length, the second length being a thickness of a portion of each of the first gate insulating layers that is not shared with another of the first gate insulating layers.

3. The memory device using a pillar-shaped semiconductor element according to claim 2, wherein in plan view, an outer peripheral edge of the respective first gate insulating layers surrounding the first semiconductor pillar and the second semiconductor pillar and an outer peripheral edge of the respective first gate insulating layers surrounding the third semiconductor pillar and the fourth semiconductor pillar are spaced apart from each other in a direction perpendicular to the first straight line.

4. The memory device using a pillar-shaped semiconductor element according to claim 1, wherein the second gate conductor layer and the third gate conductor layer are connected to each other in plan view.

5. The memory device using a pillar-shaped semiconductor element according to claim 3, wherein in plan view, the first gate conductor layer and the fourth gate conductor layer are connected to gate conductor layers lying at outer peripheral portions of pluralities of semiconductor pillars outwardly adjacent to the first to fourth semiconductor pillars and lying in the same layer as the first gate conductor layer and the fourth gate conductor layer.

6. The memory device using a pillar-shaped semiconductor element according to claim 1, wherein in plan view, respective first outer peripheral edges of the fifth to eighth semiconductor pillars surrounded by the second gate insulating layers are positioned inside respective second outer peripheral edges of the first to fourth semiconductor pillars surrounded by the first gate insulating layers.

7. The memory device using a pillar-shaped semiconductor element according to claim 1, wherein the memory device is configured to perform the data write operation for holding a hole group or an electron group serving as majority carriers generated by an impact ionization phenomenon or a gate induced drain leakage current in any or all of the first to eighth semiconductor pillars, and the data erase operation for controlling the voltage to be applied to the first to sixth gate conductor layers, the voltage to be applied to the first impurity region, and the voltage to be applied to the second impurity regions to remove the hole group or the electron group serving as the majority carriers from within any or all of the first to eighth semiconductor pillars.

8. The memory device using a pillar-shaped semiconductor element according to claim 1, wherein a first gate capacitance between the first to fourth gate conductor layers and the first to fourth semiconductor pillars is larger than a second gate capacitance between the fifth to sixth gate conductor layers and the fifth to eighth semiconductor pillars.
